(19) United States
(12) Patent Application Publication
(10) Pub. No.: US 2018/0254430 A1
(43) Pub. Date: Sep. 6, 2018

(54) ORGANIC LIGHT EMITTING DIODE DISPLAY PANEL, DISPLAY APPARATUS HAVING THE SAME, AND FABRICATING METHOD THEREOF

(71) Applicant: BOE TECHNOLOGY GROUP CO., LTD., Beijing (CN)

(72) Inventor: Dejiang Zhao, Beijing (CN)

(73) Assignee: BOE TECHNOLOGY GROUP CO., LTD., Beijing (CN)

(21) Appl. No.: 15/560,762

(22) PCT Filed: Oct. 9, 2016
(86) PCT No.: PCT/CN2016/101561

§ 371 Date: Sep. 22, 2017

(51) Int. Cl. H01L 51/52; H01L 27/32; H01L 51/00

(52) U.S. Cl. CPC H01L 51/5221; H01L 51/0005; H01L 51/5206; H01L 27/3211

(57) ABSTRACT

The present application discloses an organic light emitting diode display panel, a display apparatus having the same, and a fabricating method thereof. The organic light emitting diode display panel has a plurality of pixels, each of which includes a subpixel region and an inter-subpixel region. The organic light emitting diode display panel includes a base substrate; a first electrode layer on the base substrate; a light emitting layer in the subpixel region on a side of the first electrode layer distal to the base substrate; a second electrode layer on a side of the light emitting layer distal to the first electrode layer; and an auxiliary electrode layer in the inter-subpixel region in a same layer as the second electrode layer, the auxiliary electrode layer and the second electrode layer being in contact with each other; the auxiliary electrode layer has a thickness larger than that of the second electrode layer.

### TECHNICAL FIELD

The present invention relates to an organic light emitting diode display panel, a display apparatus having the same, and a fabricating method thereof.

### BACKGROUND

Organic light emitting diode (OLED) display apparatuses are self-emissive devices, and do not require backlights. OLED display apparatuses also provide more vivid colors and a larger color gamut as compared to the conventional liquid crystal display (LCD) apparatuses. Further, OLED display apparatuses can be made more flexible, thinner, and lighter than a typical LCD.

An OLED display apparatus typically includes an anode, an organic layer including a light emitting layer, and a cathode. OLEDs can either be a bottom-emission type OLED or a top-emission type OLED. In bottom-emission type OLEDs, the light is extracted from an anode side. In bottom-emission type OLEDs, the anode is generally transparent, while a cathode is generally reflective. In a top-emission type OLED, light is extracted from a cathode side. The cathode is optically transparent, while the anode is reflective.

### SUMMARY

In one aspect, the present invention provides an organic light emitting diode display panel having a plurality of pixels, each of which includes a subpixel region and an inter-subpixel region, the organic light emitting diode display panel comprising a base substrate; a first electrode layer on the base substrate; a light emitting layer in the subpixel region on a side of the first electrode layer distal to the base substrate; a second electrode layer on a side of the light emitting layer distal to the first electrode layer; and an auxiliary electrode layer in the inter-subpixel region in a same layer as the second electrode layer, the auxiliary electrode layer and the second electrode layer being in contact with each other; the auxiliary electrode layer has a thickness larger than that of the second electrode layer.

Optionally, a cross-section of the auxiliary electrode layer has a substantially inverted trapezoidal shape; a short base of the inverted trapezoidal shape being on a side of the auxiliary electrode layer proximal to the first electrode layer.

Optionally, the second electrode layer comprises a first portion substantially in the subpixel region and a second portion substantially in the inter-subpixel region; the first portion electrically connected to the auxiliary electrode layer through the second portion.

Optionally, the organic light emitting diode display panel further comprises a pixel definition layer in the inter-subpixel region on a side of the auxiliary electrode layer distal to the base substrate.

Optionally, the organic light emitting diode display panel comprises an organic layer in the subpixel region on a side of the first electrode layer distal to the base substrate, the organic layer comprising the light emitting layer; and an insulating layer in the inter-subpixel region on a side of the auxiliary electrode layer proximal to the base substrate; wherein a thickness of the organic layer is no greater than a thickness of the insulating layer.

Optionally, the organic layer further comprising one or more organic functional layer.

Optionally, the second electrode layer is a transparent electrode layer made of a transparent metal material.

Optionally, the auxiliary electrode layer is a non-transparent electrode layer made of a non-transparent metal material.

Optionally, the first portion of the second electrode layer has a thickness in a range of approximately 5 nm to approximately 20 nm.

Optionally, the auxiliary electrode layer has a thickness in a range of approximately 50 nm to approximately 500 nm.

Optionally, the organic light emitting diode display panel is a top-emission type display panel, the first electrode layer is an anode layer, the second electrode layer is a cathode layer, and the auxiliary electrode layer is an auxiliary cathode layer.

In another aspect, the present invention provides a method of fabricating an organic light emitting diode display panel having a plurality of pixels, each of which includes a subpixel region and an inter-subpixel region, comprising forming a first electrode layer on a base substrate; forming an auxiliary electrode layer in the inter-subpixel region in a same layer as a second electrode layer, the auxiliary electrode layer and the second electrode layer being in contact with each other; the auxiliary electrode layer has a thickness larger than that of the second electrode layer; forming a light emitting layer in the subpixel region on a side of the first electrode layer distal to the base substrate; and forming a second electrode layer on a side of the light emitting layer distal to the first electrode layer.

Optionally, the auxiliary electrode layer is formed to have a cross-section having a substantially inverted trapezoidal shape; a short base of the inverted trapezoidal shape being on a side of the auxiliary electrode layer proximal to the first electrode layer.

Optionally, the method further comprises forming a pixel definition layer in the inter-subpixel region on a side of the auxiliary electrode layer distal to the base substrate.

Optionally, the step of forming the second electrode layer is performed subsequent to the step of forming the light emitting layer; the step of forming the second electrode layer comprising vapor depositing a metal material on the side of the light emitting layer distal to the first electrode layer; thereby forming a first portion of the second electrode layer substantially in the subpixel region, and a second portion substantially in the inter-subpixel region, the first portion electrically connected to the auxiliary electrode layer through the second portion.

Optionally, the first portion of the second electrode layer is formed to have a thickness in a range of approximately 5 nm to approximately 20 nm; and the auxiliary electrode layer is formed to have a thickness in a range of approximately 50 nm to approximately 500 nm.

Optionally, the method comprises forming an organic layer comprising the light emitting layer in the subpixel region on a side of the first electrode layer distal to the base substrate; and forming an insulating layer in the inter-subpixel region on a side of the auxiliary electrode layer proximal to the base substrate and on a side of the first electrode layer distal to the base substrate; wherein the organic layer is formed to have a thickness no greater than a thickness of the insulating layer.

Optionally, the organic layer is formed by an ink jet printing process.

Optionally, the second electrode layer is formed by a transparent metal material.

In another aspect, the present invention provides a display apparatus comprising an organic light emitting diode display panel described herein or fabricated by a method described herein.

### BRIEF DESCRIPTION OF THE FIGURES

The following drawings are merely examples for illustrative purposes according to various disclosed embodiments and are not intended to limit the scope of the present invention.

FIG. 1 is a diagram illustrating the structure of an organic light emitting diode display panel in some embodiments.

FIG. 2 is a diagram illustrating the structure of an organic light emitting diode display panel in some embodiments.

FIG. 3 is a diagram illustrating the structure of an organic light emitting diode display panel in some embodiments.

FIG. 4 is a diagram illustrating a process of fabricating an auxiliary electrode layer in some embodiments.

FIGS. 5A-5D illustrate a process of fabricating an organic light emitting diode display panel in some embodiments.

### DETAILED DESCRIPTION

The disclosure will now describe more specifically with reference to the following embodiments. It is to be noted that the following descriptions of some embodiments are presented herein for purpose of illustration and description only. It is not intended to be exhaustive or to be limited to the precise form disclosed.

In a top-emission type OLED, the cathode may be formed from a transparent conductive material such as indium tin oxide and/or thin transparent metals such as magnesium and silver. A metal cathode may have better electrical conductivity than a cathode formed from indium tin oxide. However, a metal cathode must be made very thin in order to be optically transparent. In a thin metal layer, the sheet resistance is relatively large, as compared to one having a larger thickness (e.g., the anode). Due to the large sheet resistance, greater power may be required to operate the top-emission type OLED. This issue becomes particularly challenging in large-size display panels.

In some embodiments, the cathode may be made of a transparent indium tin oxide material. Because indium tin oxide is a transparent material, the cathode made of indium tin oxide may have a relatively larger thickness. However, typically indium tin oxide can only be effectively deposited on a substrate by sputtering. It was discovered in the present disclosure that the sputtering process of indium tin oxide damages the organic layer, resulting in a reduced life time and inferior properties.

In some embodiments, an auxiliary electrode may be added in a layer on top of the cathode layer, electrically connected to cathode through a via. However, it was discovered in the present disclosure that sometimes at least some of the vias may be covered or clogged during the process of forming the auxiliary electrode using a mask plate. As a result, the auxiliary electrode is not electrically connected to the cathode, leading to defects in image display, e.g., mura defects.

Accordingly, the present invention provides, inter alia, an organic light emitting diode display panel having a novel structure, a display apparatus having the same, and a fabricating method thereof that substantially obviate one or more of the problems due to limitations and disadvantages of the related art. In one aspect, the present invention provides an organic light emitting diode display panel having a plurality of pixels, each of which includes a subpixel region and an inter-subpixel region. In some embodiments, the organic light emitting diode display panel includes a base substrate; a first electrode layer on the base substrate; a light emitting layer in the subpixel region on a side of the first electrode layer distal to the base substrate; a second electrode layer on a side of the light emitting layer distal to the first electrode layer; and an auxiliary electrode layer in the inter-subpixel region in a same layer as the second electrode layer. The auxiliary electrode layer and the second electrode layer are in contact with each other; and the auxiliary electrode layer has a thickness larger than that of the second electrode layer.

Optionally, a cross-section of the auxiliary electrode layer has a substantially inverted trapezoidal shape. A short base of the inverted trapezoidal shape is on a side of the auxiliary electrode layer proximal to the first electrode layer, i.e., a long base of the inverted trapezoidal shape is on a side of the auxiliary electrode layer distal to the first electrode layer.

As used herein, a subpixel region refers to a light emission region of a subpixel, such as a region corresponding to a light emissive layer in an organic light emitting diode display. Optionally, a pixel may include a number of separate light emission regions corresponding to a number of subpixels in the pixel. Optionally, the subpixel region is a light emission region of a red color subpixel. Optionally, the subpixel region is a light emission region of a green color subpixel. Optionally, the subpixel region is a light emission region of a blue color subpixel. Optionally, the subpixel region is a light emission region of a white color subpixel.

As used herein, an inter-subpixel region refers to a region between adjacent subpixel regions, such as a region corresponding a pixel definition layer in an organic light emitting diode display. Optionally, the inter-subpixel region is a region between adjacent subpixel regions in a same pixel. Optionally, the inter-subpixel region is a region between two adjacent subpixel regions from two adjacent pixels. Optionally, the inter-subpixel region is a region between a subpixel region of a red color subpixel and a subpixel region of an adjacent green color subpixel. Optionally, the inter-subpixel region is a region between a subpixel region of a red color subpixel and a subpixel region of an adjacent blue color subpixel. Optionally, the inter-subpixel region is a region between a subpixel region of a green color subpixel and a subpixel region of an adjacent blue color subpixel.

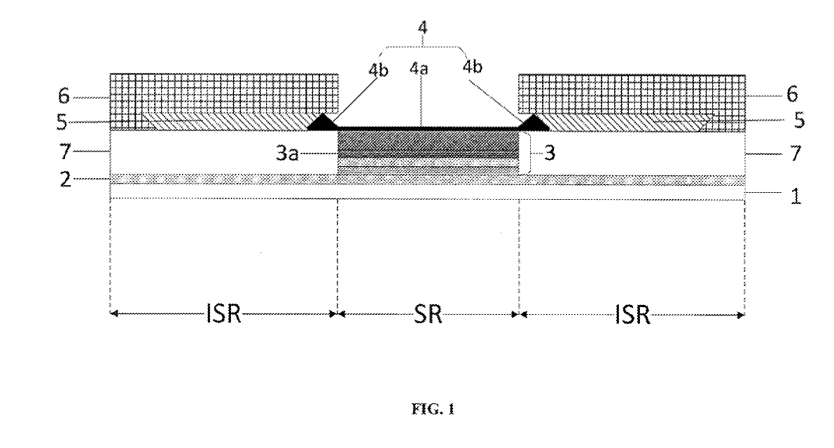

FIG. 1 is a diagram illustrating the structure of an organic light emitting diode display panel in some embodiments. Referring to FIG. 1, the organic light emitting diode display panel in the embodiment includes a plurality of pixels, each of which includes a subpixel region SR and an inter-subpixel region ISR. The organic light emitting diode display panel includes a base substrate 1; a first electrode layer 2 on the base substrate 1; a light emitting layer 3a in the subpixel region SR on a side of the first electrode layer 2 distal to the base substrate 1; a second electrode layer 4 on a side of the light emitting layer 3a distal to the first electrode layer 2; and an auxiliary electrode layer 5 in the inter-subpixel region ISR in a same layer as the second electrode layer 4. As shown in FIG. 1, the auxiliary electrode layer 5 and the second electrode layer 4 are electrically connected and in contact with each other. The auxiliary electrode layer 5 has a thickness larger than that of the second electrode layer 4. Optionally, the light emitting layer 3a is a sub-layer of an organic layer 3 in the organic light emitting diode display panel. Optionally, the organic layer 3 further includes one or more additional organic functional layer.

Optionally, the first electrode layer 2 is an anode, and the second electrode layer 4 is a cathode.

Any appropriate electrode materials and any appropriate fabricating methods may be used to make the first electrode layer, the second electrode layer, and the auxiliary electrode layer. For example, an electrode material may be deposited on the base substrate (e.g., by sputtering or vapor deposition); and patterned (e.g., by lithography such as a wet etching process) to form these electrode layers. Examples of appropriate electrode materials include, but are not limited to, non-transparent metal materials such as silver, magnesium, aluminum, platinum, gold, copper, neodymium, lithium, and nickel; transparent electrode materials such as indium tin oxide, indium zinc oxide; transparent metals (e.g., nano-silver), and a combination (e.g., alloys or laminates) thereof.

In some embodiments, the organic light emitting diode display panel is a top-emission type display panel, the first electrode layer is an anode layer, the second electrode layer is a cathode layer, and the auxiliary electrode layer is an auxiliary cathode layer. In a top-emission type display panel, the second electrode layer is a transparent electrode layer, and the first electrode layer is optionally a non-transparent electrode layer. Because the auxiliary electrode layer is disposed in the inter-subpixel region, it may be a non-transparent electrode layer. Optionally, the first electrode layer is made of a non-transparent electrode material. Optionally, the second electrode layer is a transparent electrode layer made of a transparent electrode material, e.g., a transparent electrode material suitable for vapor deposition. Optionally, the second electrode layer is a transparent electrode layer made of a transparent metal material, e.g., a transparent silver material. Optionally, the second electrode layer is a transparent metal electrode layer, and the auxiliary electrode layer is a non-transparent metal electrode layer, and the second electrode layer and the auxiliary electrode layer are made of a same metal material.

In a top-emission type display panel, the cathode made of a metal material is typically made be very thin in order to be optically transparent. By having an auxiliary cathode layer electrically connected to the cathode, the resistance of the cathode layer may be significantly reduced. The auxiliary cathode is disposed in the inter-subpixel region, thus it can be made thicker than the cathode layer. In some embodiments, the cathode layer and the auxiliary cathode layer are in a same layer and in contact with each other, and the cathode layer has a thickness much smaller than that of the auxiliary cathode layer.

In some embodiments, a ratio between the thickness of the auxiliary cathode layer to the thickness of the cathode layer is in a range of approximately 10 to approximately 100. Optionally, the cathode layer (e.g., a portion of the cathode layer in the subpixel region) has a thickness in a range of approximately 5 nm to approximately 20 nm, e.g., approximately 5 nm to approximately 10 nm, approximately 10 nm to approximately 15 nm, and approximately 15 nm to approximately 20 nm. Optionally, the portion of the cathode layer in the subpixel region has a thickness of approximately 10 nm. Optionally, the auxiliary electrode layer has a thickness in a range of approximately 50 nm to approximately 500 nm, e.g., approximately 50 nm to approximately 100 nm, approximately 100 nm to approximately 200 nm, approximately 200 nm to approximately 300 nm, approximately 300 nm to approximately 400 nm, and approximately 400 nm to approximately 500 nm. Optionally, the auxiliary electrode layer has a thickness of approximately 300 nm.

Referring to FIG. 1, the organic light emitting diode display panel in the embodiment further includes a pixel definition layer 6 in the inter-subpixel region ISR on a side of the auxiliary electrode layer 5 distal to the base substrate 1.

Any appropriate pixel definition materials and any appropriate fabricating methods may be used to make the pixel definition layer. For example, a pixel definition material may be deposited on the base substrate by a plasma-enhanced chemical vapor deposition (PECVD) process or a spin coating process. Examples of appropriate pixel definition materials include, but are not limited to, silicon oxide (SiO_{y}), silicon nitride (SiN_{y}, e.g., Si₃N₄), silicon oxynitride (SiOₓN_{y}), polyimide, polyamide, acryl resin, benzocyclobutene, and phenol resin. Optionally, the pixel definition layer may have a single-layer structure or a stacked-layer structure including two or more sub-layers (e.g., a stacked-layer structure including a silicon oxide sublayer and a silicon nitride sublayer). Optionally, the pixel definition layer divides each of the plurality of pixels into the subpixel region and the inter-subpixel region.

Referring to FIG. 1, in some embodiments, the organic light emitting diode display panel includes an organic layer 3 in the subpixel region SR on a side of the first electrode layer 2 distal to the base substrate 1, and the light emitting layer 3a is a sub-layer of the organic layer 3. Optionally, the organic layer 3 further includes one or more organic functional layer.

In some embodiments, the organic layer includes one or more organic functional layer between the light emitting layer and the first electrode layer in the subpixel region. Optionally, the one or more organic functional layer includes a carrier transport layer such as a hole transport layer. Optionally, the one or more organic functional layer includes a carrier injection layer such as a hole injection layer. Optionally, the organic layer includes a hole injection layer on a side of the first electrode layer distal to the base substrate, a hole transport layer on a side of the hole injection layer distal to the first electrode layer, and a light emitting layer on a side of the hole transport layer distal to the hole injection layer.

In some embodiments, the organic layer includes one or more organic functional layer between the light emitting layer and the second electrode layer in the subpixel region. Optionally, the one or more organic functional layer includes a carrier transport layer such as an electron transport layer. Optionally, the one or more organic functional layer includes a carrier injection layer such as an electron injection layer. Optionally, the organic layer includes an electron transport layer on a side of the light emitting layer distal to the first electrode layer, and an electron injection layer on a side of the electron transport layer distal to the light emitting layer.

Optionally, the organic layer includes a hole injection layer on a side of the first electrode layer distal to the base substrate, a hole transport layer on a side of the hole injection layer distal to the first electrode layer, a light emitting layer on a side of the hole transport layer distal to the hole injection layer, an electron transport layer on a side of the light emitting layer distal to the hole transport layer, and an electron injection layer on a side of the electron transport layer distal to the light emitting layer.

Referring to FIG. 1, in some embodiments, the organic light emitting diode display panel further includes an insulating layer 7 in the inter-subpixel region ISR on a side of the auxiliary electrode layer 5 proximal to the base substrate 1 (i.e., on a side of the first electrode layer 2 distal to the base substrate 1).

Any appropriate insulating materials and any appropriate fabricating methods may be used to make the insulating layer. For example, an insulating material may be deposited on the base substrate by a plasma-enhanced chemical vapor deposition (PECVD) process or a spin coating process. Examples of appropriate insulating materials include, but are not limited to, silicon oxide (SiO_{y}), silicon nitride (SiN_{y}, e.g., Si₃N₄), silicon oxynitride (SiOₓN_{y}), polyimide resin and polyester resin. Optionally, the insulating layer may have a single-layer structure or a stacked-layer structure including two or more sub-layers (e.g., a stacked-layer structure including a silicon oxide sublayer and a silicon nitride sublayer).

Optionally, the organic layer and the insulating layer are in a same layer. For example, the organic layer is in the subpixel region on a side of the first electrode layer distal to the base substrate, and the insulating layer is in the inter-subpixel region on a side of the first electrode layer distal to the base substrate. Optionally, the thickness of the organic layer is no greater than a thickness of the insulating layer so that the organic layer is not electrically connected to the auxiliary electrode layer on the insulating layer. Optionally, the organic layer and the insulating layer have a substantially the same thickness. Optionally, a surface of the organic layer on a side distal to the first electrode layer is substantially on a same level as a surface of the insulating layer distal to the base substrate. Optionally, a surface of the organic layer on a side distal to the first electrode layer is on a level lower than a surface of the insulating layer distal to the base substrate.

Referring to FIG. 1, the second electrode layer 4 in the embodiment includes a first portion 4a substantially in the subpixel region SR and a second portion 4b substantially in the inter-subpixel region ISR. The first portion 4a is electrically connected to the auxiliary electrode layer 5 through the second portion 4b. In some cases, the second portion 4b may be considered as a connecting structure for electrically connecting the first portion 4a and the auxiliary electrode layer 5. Optionally, the first portion 4a and the second portion 4b are made of a same material (and in a same process). Optionally, the first portion 4a, the second portion 4b, and the auxiliary electrode layer 5 are made of a same material, however, the auxiliary electrode layer 5 is made in a process separate from that for the first portion 4a and the second portion 4b. Optionally, the first portion 4a and the second portion 4b are made of a material different from that of the auxiliary electrode layer 5, and are made in a process separate from that for the auxiliary electrode layer 5.

The auxiliary electrode layer and the second electrode layer, and portions thereof may have various appropriate shapes. Referring to FIG. 1, the auxiliary electrode layer 5 has a cross-section having a substantially inverted trapezoidal shape. In FIG. 1, the second portion 4b of the second electrode layer 4 has a cross-section having a substantially triangular shape. Putting two together, the cross-sections of the auxiliary electrode layer 5 and the second portion 4b in the inter-subpixel region ISR have a substantially parallelogram shape. Optionally, the cross-section of the auxiliary electrode layer has a substantially rectangular shape.

Optionally, the second portion 4b of the second electrode layer 4 has a cross-section having an irregular shape.

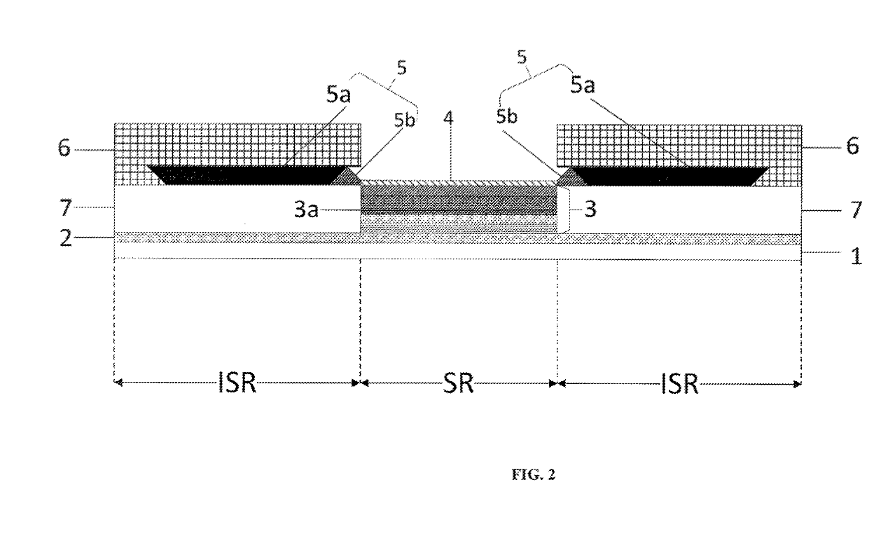

FIG. 2 is a diagram illustrating the structure of an organic light emitting diode display panel in some embodiments. Referring to FIG. 2, the second electrode layer 4 is substantially limited in the subpixel region SR, and the auxiliary electrode layer 5 is substantially limited in the inter-subpixel region ISR. The auxiliary electrode layer 5 includes a first portion 5a and a second portion 5b. The second electrode layer 4 is electrically connected to the first portion 5a of the auxiliary electrode layer 5 through the second portion 5b. The second portion 5b may be considered as a connecting structure for electrically connecting the first portion 5a and the second electrode layer 4. Optionally, the second portion 5b and the second electrode layer 4 are made of a same material (and in a same process). Optionally, the first portion 5a, the second portion 5b, and the second electrode layer 4 are made of a same material, however, the first portion 5a is made in a process separate from that for the second portion 5b and the second electrode layer 4. Optionally, the second portion 5b and the second electrode layer 4 are made of a material different from that of the first portion 5a, and are made in a process separate from that for the first portion 5a.

The auxiliary electrode layer 5 in FIG. 2 has a cross-section having a substantially parallelogram shape. The first portion 5a has a cross-section having a substantially inverted trapezoidal shape. In FIG. 2, the second portion 5b has a cross-section having a substantially triangular shape. Putting two together, the cross-sections of the first portion 5a and the second portion 5b in the inter-subpixel region ISR have a substantially parallelogram shape. Optionally, the cross-section of the auxiliary electrode layer 5 has a substantially rectangular shape.

Optionally, the second portion 5b of the auxiliary electrode layer 5 has a cross-section having an irregular shape.

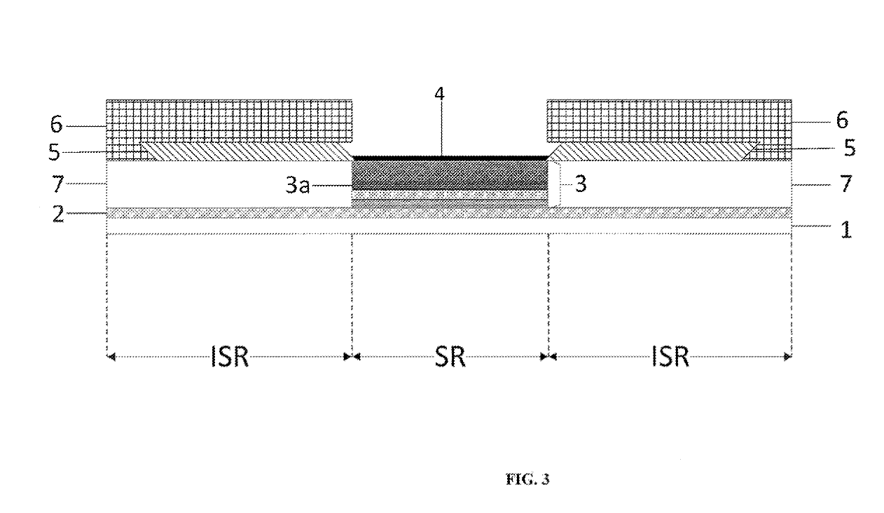

Numerous alternative embodiments may be practiced to make the second electrode layer and the auxiliary electrode layer. For example, in some embodiments, the auxiliary electrode layer is an integral electrode layer in the inter-subpixel region, and the second electrode layer is an integral electrode layer in the subpixel region. FIG. 3 is a diagram illustrating the structure of an organic light emitting diode display panel in some embodiments. Referring to FIG. 3, the auxiliary electrode layer 5 has a cross-section having a substantially parallelogram shape. Optionally, the cross-section of the auxiliary electrode layer 5 has a substantially rectangular shape. Optionally, the auxiliary electrode layer 5 and the second electrode layer 4 are made of different materials and in separate processes. Optionally, the auxiliary electrode layer 5 and the second electrode layer 4 are made of a same material but in separate processes.

In another aspect, the present disclosure provides a method of fabricating an organic light emitting diode display panel having a plurality of pixels, each of which includes a subpixel region and an inter-subpixel region. In some embodiments, the method includes forming a first electrode layer on the base substrate; forming an auxiliary electrode layer in the inter-subpixel region in a same layer as the second electrode layer; forming a light emitting layer in the subpixel region on a side of the first electrode layer distal to the base substrate; and forming a second electrode layer on a side of the light emitting layer distal to the first electrode layer. The auxiliary electrode layer and the second electrode layer are formed to be in contact with each other; and the auxiliary electrode layer is formed to have a thickness larger than that of the second electrode layer. Optionally, the second electrode layer is formed to have a first portion substantially in the subpixel region and a second portion substantially in the inter-subpixel region; the first portion electrically connected to the auxiliary electrode layer through the second portion.

Any appropriate electrode materials and any appropriate fabricating methods may be used to make the first electrode layer, the second electrode layer, and the auxiliary electrode layer. For example, an electrode material may be deposited on the base substrate and patterned (e.g., by lithography such as a wet etching process) to form these electrode layers. Examples of deposition methods include, but are not limited to, sputtering (e.g., magnetron sputtering) and evaporation coating (e.g., a Chemical Vapor Deposition method, a Plasma-Enhanced Chemical Vapor Deposition (PECVD) method, a thermal vapor deposition method). In a magnetron sputtering process, magnetron sputtering apparatus induces plasma ions of a gas to bombard a target, causing surface atoms of the target material to be ejected and deposited as a film or layer on the surface of a substrate. For example, a metal electrode material or indium tin oxide may be used as the sputtering target, and a plasma including argon is used to bombard the sputtering target. Examples of appropriate electrode materials include, but are not limited to, non-transparent metal materials such as silver, magnesium, aluminum, platinum, gold, copper, neodymium, lithium, and nickel; transparent electrode materials such as indium tin oxide, indium zinc oxide; transparent metals (e.g., nano-silver), and a combination (e.g., alloys or laminates) thereof.

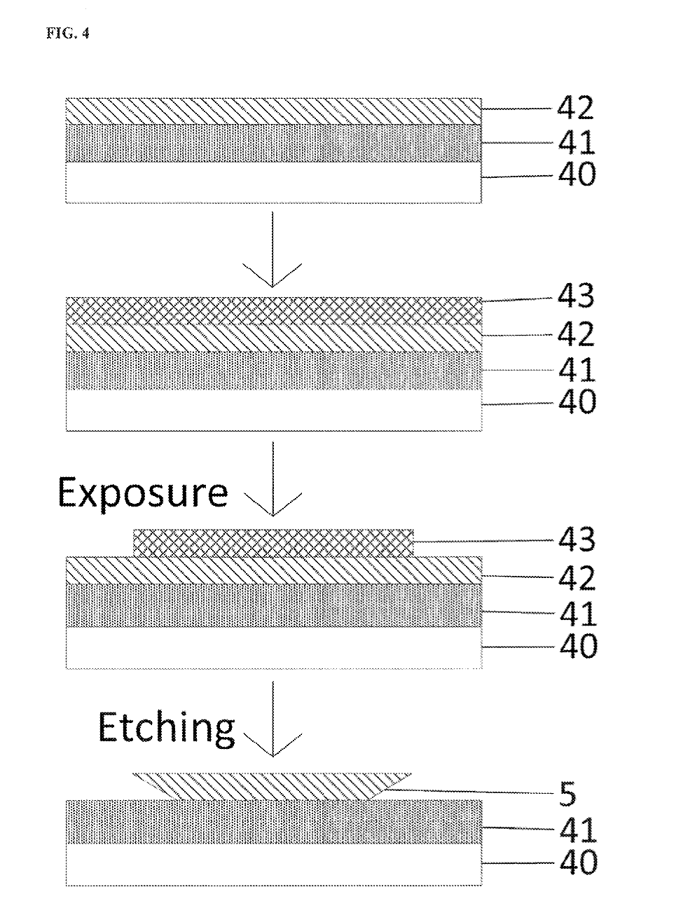

In some embodiments, the auxiliary electrode layer is fabricated by a lithography process. FIG. 4 is a diagram illustrating a process of fabricating an auxiliary electrode layer in some embodiments. Referring to FIG. 4, the lithography process in the embodiment includes depositing an auxiliary electrode material on a side of an insulating layer 41 distal to the base substrate 40, thereby forming an auxiliary electrode material layer 42. The process further includes depositing a photoresist layer 43 on a side of the auxiliary electrode material layer 42 distal to the insulating layer 41; exposing the photoresist layer 43 to UV light using a mask plate having a pattern corresponding to that of the auxiliary electrode layer; and removing the photoresist layer 43 in exposed regions. The photoresist layer 43 in a region corresponding to the auxiliary electrode layer remains. The auxiliary electrode material in the exposed region is then removed by etching, e.g., by wet etching, thereby forming an auxiliary electrode layer 5.

As shown in FIG. 4, the auxiliary electrode layer 5 has a cross-section having a substantially inverted trapezoidal shape. A short base of the inverted trapezoidal shape is on a side of the auxiliary electrode layer 5 proximal to the insulating layer 41, i.e., a long base of the inverted trapezoidal shape is on a side of the auxiliary electrode layer 5 distal to the insulating layer 41. Optionally, the auxiliary electrode layer 5 has a cross-section having a substantially rectangular shape. Optionally, the auxiliary electrode layer 5 has a cross-section having a substantially parallelogram shape.

Optionally, the lithography process further includes baking the photoresist layer subsequent to removal of photoresist material in exposed regions and prior to etching of the auxiliary electrode material in the exposed region. Optionally, the baking parameters may be controlled to achieve a degree of hardness in the remaining photoresist layer 43. For example, the hardness of the remaining photoresist layer 43 may be adjusted by controlling the baking temperature, the baking duration, or a combination thereof. A relatively harder photoresist layer facilitates the formation of an auxiliary electrode layer 5 that has a cross-section having a substantially inverted trapezoidal shape.

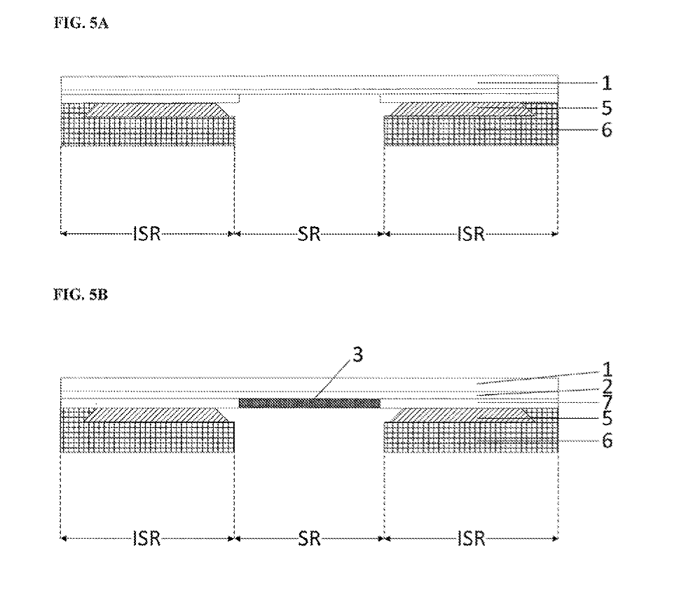

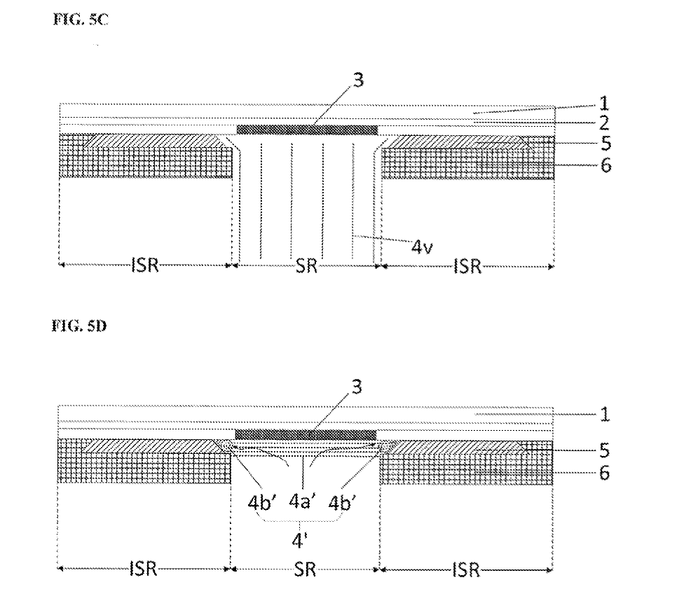

In some embodiments, subsequent to forming the second electrode layer, the method further includes forming a pixel definition layer in the inter-subpixel region on a side of the auxiliary electrode layer distal to the base substrate. FIGS. 5A-5D illustrate a process of fabricating an organic light emitting diode display panel in some embodiments. Referring to FIG. 5A, a pixel definition layer 6 is formed on a side of the auxiliary electrode layer 5 distal to the base substrate 1. The pixel definition layer 6 defines a subpixel region SR and an inter-subpixel region ISR in the display panel.

Referring to FIG. 5B, the method further includes forming an organic layer 3 (which includes a light emitting layer) in the subpixel region SR on a side of the first electrode layer 2 distal to the base substrate 1. Optionally, the thickness of the organic layer 3 is no greater than the thickness of the insulating layer 7. In FIG. 5B, the thickness of the organic layer 3 is substantially the same as the thickness of the insulating layer 7. Optionally, a surface of the organic layer 3 on a side distal to the first electrode layer 2 is substantially on a same level as a surface of the insulating layer 7 distal to the base substrate 1. Optionally, a surface of the organic layer 3 on a side distal to the first electrode layer 2 is on a level lower than a surface of the insulating layer 7 distal to the base substrate 1.

Various appropriate methods may be used to make the organic layer. For example, the light emitting layer and/or other organic functional layer of the organic layer may be formed by deposition methods or ink-jet printing methods. Examples of deposition methods include, but are not limited to, evaporation coating (e.g., a Chemical Vapor Deposition method, a Plasma-Enhanced Chemical Vapor Deposition (PECVD) method, a thermal vapor deposition method). Optionally, the organic layer is formed by ink-jet printing.

Referring to FIG. 5C, the method further includes forming a second electrode layer on a side of the organic layer 3 distal to the first electrode layer 2 by vapor depositing an electrode material 4v. Optionally, the electrode material 4v is a metal material. In some examples, the electrode material is disposed in a vessel, and heated to cause the electrode material to evaporate (e.g., sublime). The vapor deposition rate may be controlled by the amount of heat applied to the electrode material. The thickness of the second electrode layer may be controlled by the vapor deposition rate and vapor deposition duration. As shown in FIG. 5C, the electrode material 4v evaporates and disperses from the vessel to the substrate having the organic layer 3 in the subpixel region SR.

Referring to FIG. 5D, when the vapor reaches the surface of the subpixel region SR, the vapor will disperse along the surface to two sides of the surface. Due to the shape of the auxiliary electrode layer 5, the vapor is prone to condense to a greater degree in regions at the interface between the subpixel region SR and the inter-subpixel region ISR. For example, the cross-section of the auxiliary electrode layer 5 may have an inverted trapezoidal shape, resulting in a groove region at the interface (corresponding to 4b′ in FIG. 5D) having a triangular shaped cross-section. Due to constraint of the groove structure, the vapor deposits more easily inside the groove, forming electrode material deposition 4b′ in the inter-subpixel region ISR. The vapor also deposits on the surface of the organic layer 3, forming electrode material deposition 4a′ in the subpixel region SR. When the vapor deposition process is complete, the second electrode layer is formed on a side of the organic layer 3 distal to the first electrode layer 2. The second electrode layer so formed includes a first portion substantially in the subpixel region SR, and a second portion substantially in the inter-subpixel region ISR, the first portion electrically connected to the auxiliary electrode layer 5 through the second portion. When the electrode material is a metal material, the second electrode layer is a thin film. Optionally, the first portion of the second electrode layer is formed to have a thickness in a range of approximately 5 nm to approximately 20 nm; and the auxiliary electrode layer is formed to have a thickness in a range of approximately 50 nm to approximately 500 nm.

The auxiliary electrode layer may have various appropriate shapes forming a structure (e.g., a groove structure) at the interface between the subpixel region and the inter-subpixel region to induce deposition of the electrode material vapor at the interface. For example, the cross-section of the structure (e.g., the groove structure) at the interface may have various appropriate shapes, including a triangular shape, a round shape, a square shape, a rectangular shape, or an irregular shape, as long as the shapes provide sufficient constraint to facilitate vapor deposition inside the groove.

By having an auxiliary electrode layer, the resistance of the second electrode layer (e.g., a cathode) may be significantly reduced. By vapor depositing an electrode material to form the second electrode layer, damage to the organic layer during the electrode material deposition process (e.g., by sputtering) may be obviated. The present method provides an organic light emitting diode display panel have superior display qualities and an extended life time.

In another aspect, the present disclosure provides a display apparatus having an organic light emitting diode display panel described herein or fabricated by a method described herein. Examples of appropriate display apparatuses include, but are not limited to, an electronic paper, a mobile phone, a tablet computer, a television, a monitor, a notebook computer, a digital album, a GPS, etc.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An organic light emitting diode display panel having a plurality of pixels, each of which includes a subpixel region and an inter-subpixel region, the organic light emitting diode display panel comprising:
a base substrate;
a first electrode layer on the base substrate;
a light emitting layer in the subpixel region on a side of the first electrode layer distal to the base substrate;
a second electrode layer on a side of the light emitting layer distal to the first electrode layer; and
an auxiliary electrode layer in the inter-subpixel region in a same layer as the second electrode layer, the auxiliary electrode layer and the second electrode layer being in contact with each other; the auxiliary electrode layer has a thickness larger than that of the second electrode layer.

2. The organic light emitting diode display panel of claim 1, wherein a cross-section of the auxiliary electrode layer has a substantially inverted trapezoidal shape; a short base of the inverted trapezoidal shape being on a side of the auxiliary electrode layer proximal to the first electrode layer.

3. The organic light emitting diode display panel of claim 1, wherein the second electrode layer comprises a first portion substantially in the subpixel region and a second portion substantially in the inter-subpixel region; the first portion electrically connected to the auxiliary electrode layer through the second portion.

4. The organic light emitting diode display panel of claim 1, further comprising a pixel definition layer in the inter-subpixel region on a side of the auxiliary electrode layer distal to the base substrate.

5. The organic light emitting diode display panel of claim 1, comprising:
an organic layer in the subpixel region on a side of the first electrode layer distal to the base substrate, the organic layer comprising the light emitting layer; and
an insulating layer in the inter-subpixel region on a side of the auxiliary electrode layer proximal to the base substrate;
wherein a thickness of the organic layer is no greater than a thickness of the insulating layer.

6. The organic light emitting diode display panel of claim 5, wherein the organic layer further comprising one or more organic functional layer.

7. The organic light emitting diode display panel of claim 1, wherein the second electrode layer is a transparent electrode layer made of a transparent metal material.

8. The organic light emitting diode display panel of claim 7, wherein the auxiliary electrode layer is a non-transparent electrode layer made of a non-transparent metal material.

9. The organic light emitting diode display panel of claim 3, wherein the first portion of the second electrode layer has a thickness in a range of approximately 5 nm to approximately 20 nm.

10. The organic light emitting diode display panel of claim 1, wherein the auxiliary electrode layer has a thickness in a range of approximately 50 nm to approximately 500 nm.

11. The organic light emitting diode display panel of claim 1, wherein the organic light emitting diode display panel is a top-emission type display panel, the first electrode layer is an anode layer, the second electrode layer is a cathode layer, and the auxiliary electrode layer is an auxiliary cathode layer.

12. A display apparatus, comprising an organic light emitting diode display panel of claim 1.

13. A method of fabricating an organic light emitting diode display panel having a plurality of pixels, each of which includes a subpixel region and an inter-subpixel region, comprising:
forming a first electrode layer on a base substrate;
forming an auxiliary electrode layer in the inter-subpixel region in a same layer as a second electrode layer, the auxiliary electrode layer and the second electrode layer being in contact with each other; the auxiliary electrode layer has a thickness larger than that of the second electrode layer;
forming a light emitting layer in the subpixel region on a side of the first electrode layer distal to the base substrate; and
forming the second electrode layer on a side of the light emitting layer distal to the first electrode layer.

14. The method of claim 13, wherein the auxiliary electrode layer is formed to have a cross-section having a substantially inverted trapezoidal shape; a short base of the inverted trapezoidal shape being on a side of the auxiliary electrode layer proximal to the first electrode layer.

15. The method of claim 13, further comprising forming a pixel definition layer in the inter-subpixel region on a side of the auxiliary electrode layer distal to the base substrate.

16. The method of claim 13, wherein the step of forming the second electrode layer is performed subsequent to the step of forming the light emitting layer; the step of forming the second electrode layer comprising:
vapor depositing a metal material on side of the light emitting layer distal to the first electrode layer, thereby forming a first portion of the second electrode layer substantially in the subpixel region, and a second portion substantially in the inter-subpixel region, the first portion electrically connected to the auxiliary electrode layer through the second portion.

17. The method of claim 16, wherein the first portion of the second electrode layer is formed to have a thickness in a range of approximately 5 nm to approximately 20 nm; and the auxiliary electrode layer is formed to have a thickness in a range of approximately 50 nm to approximately 500 nm.

18. The method of claim 13, comprising:
forming an organic layer comprising the light emitting layer in the subpixel region on a side of the first electrode layer distal to the base substrate; and
forming an insulating layer in the inter-subpixel region on a side of the auxiliary electrode layer proximal to the base substrate and on a side of the first electrode layer distal to the base substrate;
wherein the organic layer is formed to have a thickness no greater than a thickness of the insulating layer.

19. The method of claim 18, wherein the organic layer is formed by an ink jet printing process.

20. The method of claim 13, wherein the second electrode layer is formed by a transparent metal material.
